(19) United States
(12) Patent Application Publication
(10) Pub. No.: US 2001/0034073 A1
(43) Pub. Date: Oct. 25, 2001

(54) Method of manufacturing array substrate for use in liquid crystal display device

(76) Inventors: Kyo-Ho Moon, Taegu (KR); Hu-Sung Kim, Seoul (KR)

Correspondence Address: BIRCH STEWART KOLASCH & BIRCH, PO BOX 747, FALLS CHURCH, VA, 22040-0747, US

(21) Appl. No.: 09/734,562

(22) Filed: Dec. 13, 2000

(30) Foreign Application Priority Data
Dec. 13, 1999 (KR) 1999-57330

(51) Int. Cl. H01L 21/00

(52) U.S. Cl. 438/30

(57) ABSTRACT

In the manufacturing method for an array substrate of an LCD device using four masks, the invention aims to provide a constant capacitance of the capacitor through out the pixel regions. The invention provides a method of manufacturing an array substrate for use in a liquid crystal display device, including: providing a substrate; forming a gate line on the substrate using a first mask; forming sequentially a gate insulating layer, a semiconductor layer having a doped semiconductor layer, and a metal layer on the whole substrate while covering the gate line; forming a data line and an island shaped metal portion on the semiconductor layer over the gate line by patterning the metal layer using a second mask; forming a protection layer on the semiconductor layer while covering the data line and the island shaped metal portion; forming a photoresist pattern on the protection layer over the data line using a third mask to define a first interstructure; etching the first interstructure using the photoresist pattern to leave the photoresist and the layers under the photoresist over the data line and to leave the etched semiconductor layer and the gate insulating layer over the gate line to define a second interstructure; etching the second interstructure to leave the gate insulating layer on the gate line; and forming a pixel electrode covering a portion of the gate insulating layer on the gate line using a fourth mask.

### CROSS REFERENCE

This application claims the benefit of Korean Patent Application No. 1999-57330, filed on Dec. 13, 1999, under 35 U.S.C. § 119, the entirety of which is hereby incorporated by reference.

### BACKGROUND OF THE INVENTION

1. Field of the Invention

The present invention relates to a liquid crystal display device, and more particularly, to a method of manufacturing the liquid crystal display device (LCD) with a four-masks process.

2. Description of Related Art

LCD device has a lower substrate or array substrate having switching elements and pixel electrodes, and an upper substrate having a common electrode. Between the lower and upper substrates liquid crystal material is filled.

For more detailed explanation, the array substrate needs more processes than the upper substrate does. The switching element has a gate electrode, a source electrode, a drain electrode, and an active layer. The source electrode is extended from a data line and the gate electrode is extended from a gate line. The gate and data lines cross each other to form a matrix shape, and every region that is defined by crossing the gate and data lines is called a pixel region.

In order to form one layer of the array substrate, deposition process, photolithography process, and etching process are needed. Sometimes, photolithography process is said to include the deposition process and the etching process. For an array substrate, insulating material, semiconductor material, and conductive material are used.

For the insulating material, non-transparent material such as silicon nitride and silicon oxide, and a transparent polymer material such as benzocyclobutene (BCB) are used. For the active layer, there are two types: amorphous silicon and poly crystallized silicon. For conductive material, aluminum, aluminum alloy, molybdenum, tantalum, and molybdenum-tungsten alloy are used.

Chemical vapor deposition method, sputtering method and other methods are used in order to deposit the materials. For etching process, wet etching process and dry etching process are used. The wet etching process is generally used for etching the conductive material for the gate and data lines and pixel electrode. The dry etching process is generally used for smaller and more accurate pattern such as active layer and insulating layer, and some conductive layers.

Since one mask process requires deposition and lithography and etching processes, it is necessary to reduce the number of masks for manufacturing the array substrate. Thus, recently four-mask process is suggested. But, in this method, more than one layer should be etched, deteriorating uniformity of the etched layer.

Hereinafter, a manufacturing method for an array substrate is explained with reference to drawings.

FIG. 1 is a partial plane view of a typical array substrate for an LCD device. There is shown a thin film transistor “T” near the cross point of the data and gate lines 13 and 15, which also define the pixel region “P”. There is also shown a storage capacitor “Cst” that must have a first electrode and a second electrode. The gate line 15 acts as the first electrode for the capacitor “C” and the pixel electrode 17 acts as the second electrode for the capacitor “Cst”.

The storage capacitor “Cst” helps to maintain the transmitted signal to the liquid crystal material during between the transmitting signals. The storage capacitor is electrically parallel to the liquid crystal material. The storage capacitor can be formed as shown in FIG. 1 or independent of the gate line 15. The former is called storage capacitor-on-gate (Cst-on-Gate) structure, and the latter is called independent storage capacitor structure. These days the former structure shown in FIG. 1 is generally adopted.

FIGS. 2A to 2E are cross sectional view taken along line II-II of FIG. 1. The drawings illustrate manufacturing process of the array substrate according to the conventional art.

As shown in FIG. 2A, in order to form a gate line 15, first a conductive material is deposited on the substrate 11 to form a first metal layer. The conductive material is chosen from a group consisting of aluminum, molybdenum, tungsten, and so on. Sometimes dual layer structure of aluminum and chrome or tungsten is adopted. On the whole first metal layer a photoresist is coated. Then using a first mask having a gate line shape, the photoresist is exposed to light, and some of the photoresist is removed, leaving a portion of photoresist having a gate line pattern. Then, the first metal layer is etched to form a gate line and the remaining photoresist is removed.

FIG. 2B illustrates a second mask process. On the gate line 15 and the substrate, an insulating layer, a pure amorphous silicon layer, an ohmic contact layer, and a conductive material layer or second metal layer are formed and stacked sequentially. Then using a second mask, after the lithography process explained above with reference to FIG. 2A, on the gate insulating layer 19 and a semiconductor layer 21 including the ohmic contact layer, a data line 13 crossing the gate line 15 and the metal portion 13a having an island shape above the gate line 15 are formed.

FIG. 2C illustrates a third mask process. An insulating material is deposited on the whole substrate after the process shown in FIG. 2B to form a protection layer 23. Then using a third mask, photoresist 25 is only left over the data line 13 and over a portion for a thin film transistor “T” (see FIG. 1). Thus, portions of the array substrate can be divided into three portions: “A” portion having photoresist; “B” portion having a sectional structure as gate insulating layer 19, semiconductor layer 21 and protection layer 23; and “C” portion having a sectional structure as gate line 15, gate insulating layer 19, semiconductor layer 21, metal portion 13a and protection layer 23. As can be imagined from FIG. 1, “A” portion corresponds to data line portion, “B” portion to pixel region “P”, and “C” portion to storage capacitor portion “Cst”.

As shown in FIG. 2D, using the photoresist 27, “A”, “B”, and “C” portions are etched at the same time using a dry etching method. As a result, at “A” portion, layers 23, 21, 13, and 19 under the photoresist 27 are left, at “B” portion, no layer is left, and at “C” portion, the gate insulating layer 19 having a thickness “t” is left due to the etching rate and metal portion 13a shown in FIG. 2C. The gate insulating layer 19 on the gate line 15 acts as a dielectric layer of the storage capacitor “C” (see FIG. 1).

Meanwhile since the many layers are etched at one time and the gate insulating layer should remain on the gate line 15, the left gate insulating layer 19 cannot have a uniform thickness through out the whole pixel regions “P” (see FIG. 1). Thus the capacitance of the capacitor “Cst” varies according to the position of the pixel region, results in deteriorating display quality of the LCD device.

### SUMMARY OF THE INVENTION

To overcome the problems described above, preferred embodiments of the present invention provide a method of manufacturing an array substrate for use in a liquid crystal display device which can make storage capacitor on the gate line have a uniform capacitance independent of the position of the pixel region.

Preferred embodiments of the present invention further provide another method of manufacturing an array substrate for use in a liquid crystal display device having a short processing time and a high manufacturing yield.

In order to achieve the above object, the preferred embodiment of the present invention provides a method of manufacturing an array substrate for use in a liquid crystal display device, including: providing a substrate; forming a gate line on the substrate using a first mask; forming sequentially a gate insulating layer, a semiconductor layer having a doped semiconductor layer, and a metal layer on the whole substrate while covering the gate line; forming a data line and an island shaped metal portion on the semiconductor layer over the gate line by patterning the metal layer using a second mask; forming a protection layer on the semiconductor layer while covering the data line and the island shaped metal portion; forming a photoresist pattern on the protection layer over the data line using a third mask to define a first interstructure; etching the first interstructure using the photoresist pattern to leave the photoresist and the layers under the photoresist over the data line and to leave the etched semiconductor layer and the gate insulating layer over the gate line to define a second interstructure; etching the second interstructure to leave the gate insulating layer on the gate line; and forming a pixel electrode covering a portion of the gate insulating layer on the gate line using a fourth mask.

In an another aspect of the invention, the preferred embodiment of the present invention further provides a method of manufacturing an array panel for use in a liquid crystal display device, including: providing a substrate; forming a gate line on the substrate using a first mask; forming sequentially a gate insulating layer, a semiconductor layer having a doped semiconductor layer, and a metal layer on the whole substrate while covering the gate line; forming a data line and an island shaped metal portion on the semiconductor layer over the gate line by patterning the metal layer using a second mask; forming a protection layer on the semiconductor layer while covering the data line and the island shaped metal portion; forming a photoresist pattern on the protection layer over the data line using a third mask to define a first interstructure; etching the first interstructure using the photoresist pattern to leave the photoresist, the layers under the photoresist over the data line and to leave the island shaped metal portion, semiconductor layer, and the gate insulating layer over the gate line to define a second interstructure; etching the second interstructure to leave the semiconductor layer and the gate insulating layer on the gate line to define a third interstructure; etching the third interstructure to remove the semiconductor layer and the gate insulating layer on the gate line; and forming a pixel electrode covering a portion of the gate insulating layer on the gate line using a fourth mask.

### BRIEF DESCRIPTION OF THE DRAWINGS

For a more complete understanding of the present invention and the advantages thereof, reference is now made to the following descriptions taken in conjunction with the accompanying drawings, in which like reference numerals denote like parts, and in which:

FIG. 1 is a partial plan view illustrating a typical array substrate for a liquid crystal display (LCD) device;

FIGS. 2A to 2D are cross sectional views, illustrating progress steps for manufacturing the array substrate of FIG. 1, taken along lines II-II of FIG. 1;

FIGS. 3A to 3F are cross sectional views, illustrating progress steps for manufacturing the array substrate according to a first embodiment of the invention, taken along lines II-II of FIG. 1; and

FIGS. 4A to 4G are cross sectional views, illustrating progress steps for manufacturing the array substrate according to a second embodiment of the invention, taken along lines II-II of FIG. 1.

### DETAILED DESCRIPTION OF PREFERRED EMBODIMENTS

Reference will now be made in detail to the preferred embodiments of the present invention, example of which is illustrated in the accompanying drawings.

An embodiment of the invention suggests method of forming a uniform dielectric layer by adopting two etching steps at a third mask process.

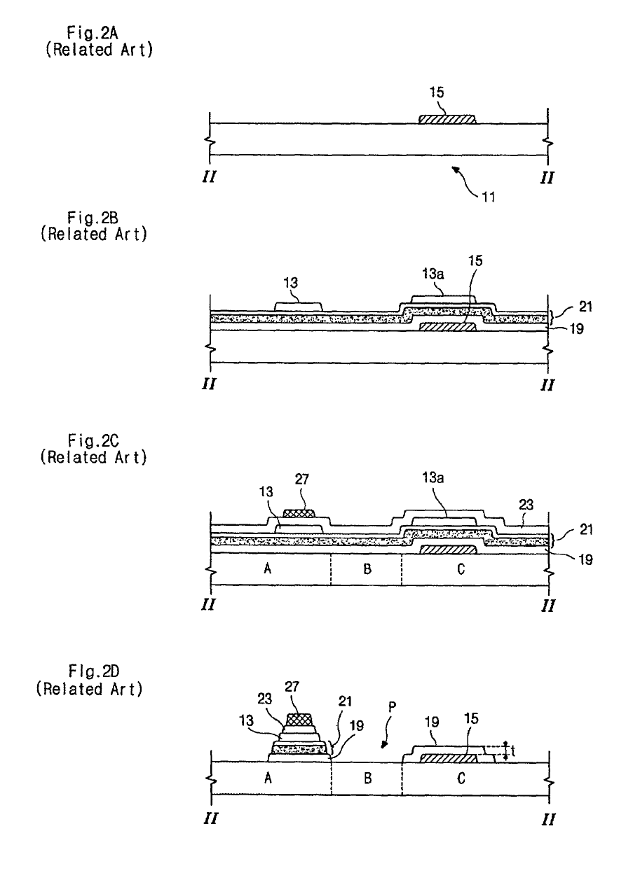

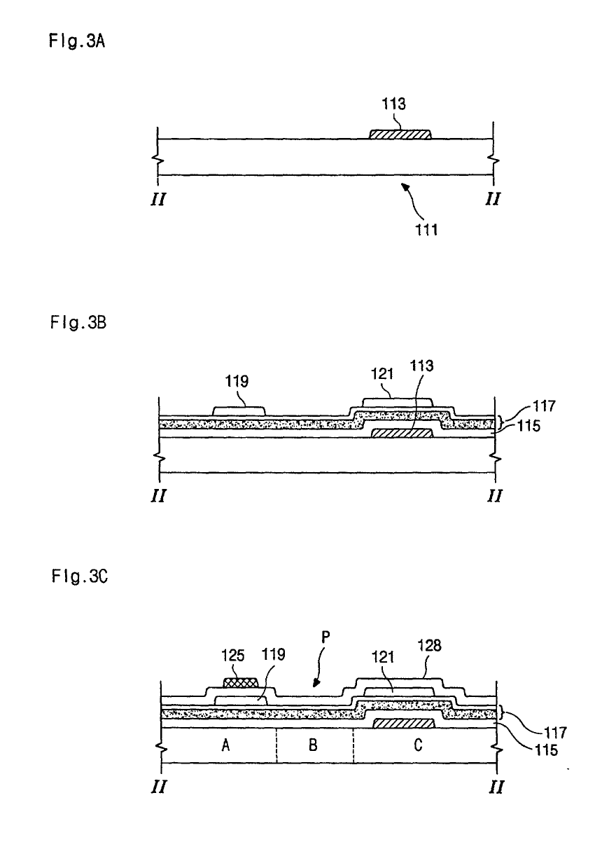

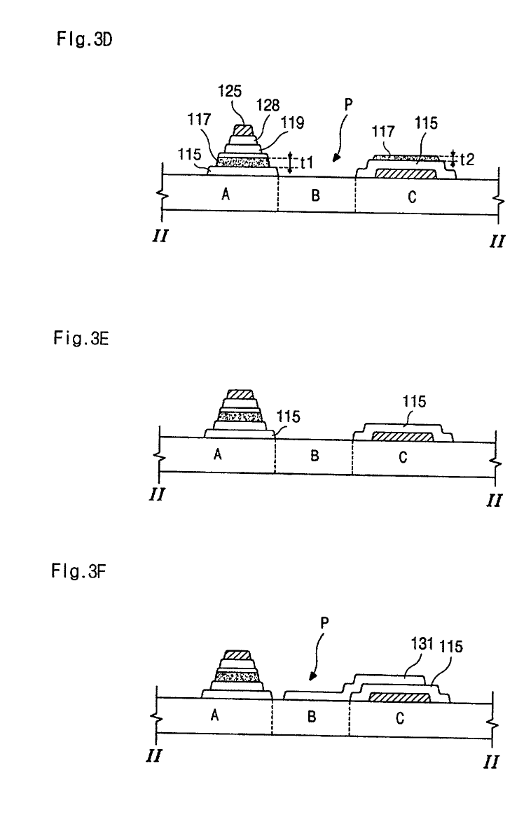

FIGS. 3A to 3E illustrate a method of manufacturing an array substrate for LCD device according to a first embodiment. The processes illustrated in FIGS. 3A to 3C are similar to those illustrated in FIGS. 2A to 2C, thus the detailed description is omitted.

On the substrate 111 metallic materials are deposited to form a first metal layer. Next, using a first mask and through a photolithography process, a gate line 113 is formed. Next, a gate insulating layer 115, a semiconductor layer 117, and a second metal layer are formed sequentially on the whole substrate 111 while covering the gate line 113. The second metal layer has metallic material such as molybdenum or tantalum, which can be etched by a dry etching technique. Through a second mask process, the second metal layer is patterned to form a data line 119 and an island shaped metal portion 121 over the gate line 113. Next, a protection layer 128 of insulating material is formed on the semiconductor layer 117 while covering the data line 112 and the metal portion 121.

Next, photoresist is deposited on the protection layer 128 and using a third mask, a portion 125 of the photoresist over the data line 119 remains. Thus, portions of the array substrate can be divided into three portions: “A” portion having photoresist; “B” portion having a sectional structure as gate insulating layer 115, semiconductor layer 117 and protection layer 128; and “C” portion having a sectional structure as gate line 113, gate insulating layer 115, semiconductor layer 117, metal portion 121 and protection layer 128.

The metal portion 121 is to adjust etching rate and to remain the gate insulating layer 115 only on the gate line 113, similar to metal portion 13a of FIG. 2C.

FIG. 3D shows a first etching step during the third mask process in order to remain only one layer on the gate insulating layer 115. In this step, dry etching technique is adopted. By controlling amount of etching gas, etching time and the like, at “B” portion no layer is left, at “A” portion layers under the photoresist 125 remain, and at “C” portion semiconductor layer 117 having a thickness t2 is left on the gate insulating layer 115. After the etching, the thickness of the semiconductor layer 117 on the gate insulating layer 115 at portion “C” is smaller than that of the semiconductor layer 117 under the photoresist 125 at portion “A”. The former is half of the latter, for example, which can be adjusted by controlling the etching condition.

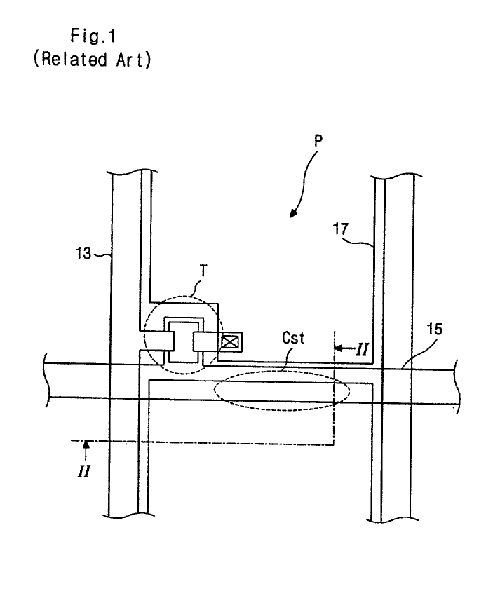

Next, as shown in FIG. 3E, only semiconductor layer 117 on the gate insulating layer 115 is etched using an etching gas having a big etching selection ratio between the semiconductor layer 117 and the insulating layer 115. In this process only one layer is etched, thus it is easy to get the gate insulating layer having a uniform thickness. Since the gate insulating layer 115 act as a dielectric layer for capacitor, uniform thickness of the gate insulating layer 115 on the gate line 113 independent of the position of the pixel region leads to a constant capacitance of the capacitor “Cst” (see FIG. 1) for the LCD device through out the whole pixel regions “P”.

After the third mask process, as shown in FIG. 3F, a transparent conductive material is deposited on the whole substrate, and using a fourth mask a pixel electrode 131 is formed. The pixel electrode is connected to the thin film transistor “T” (see FIG. 1). The pixel electrode also 131 acts as one electrode for the capacitor “Cst”, while the gate line 113 acts as the other electrode for the capacitor “Cst”.

Another embodiment of the invention suggests three times etching steps during the third mask process.

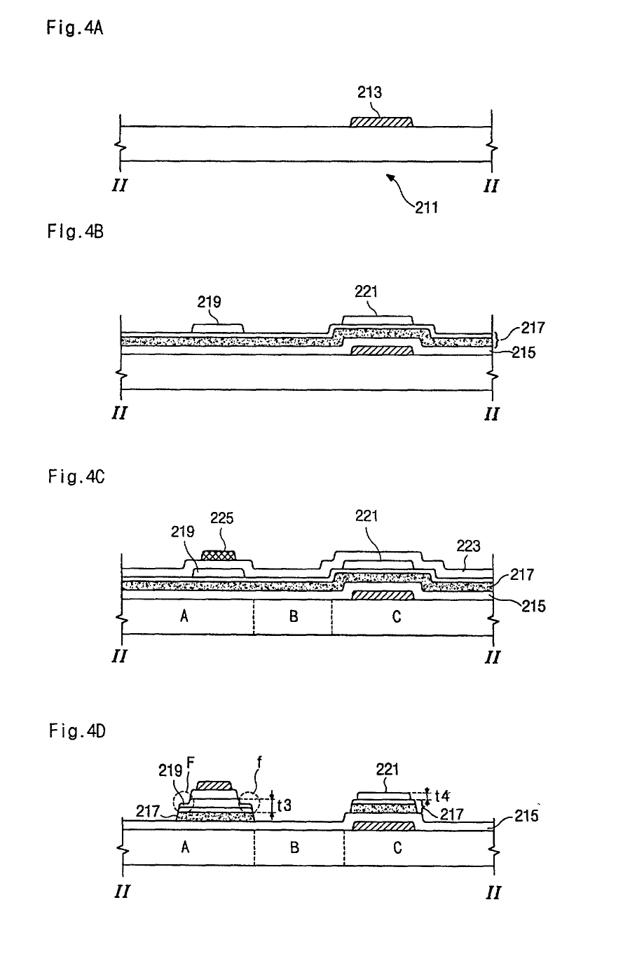

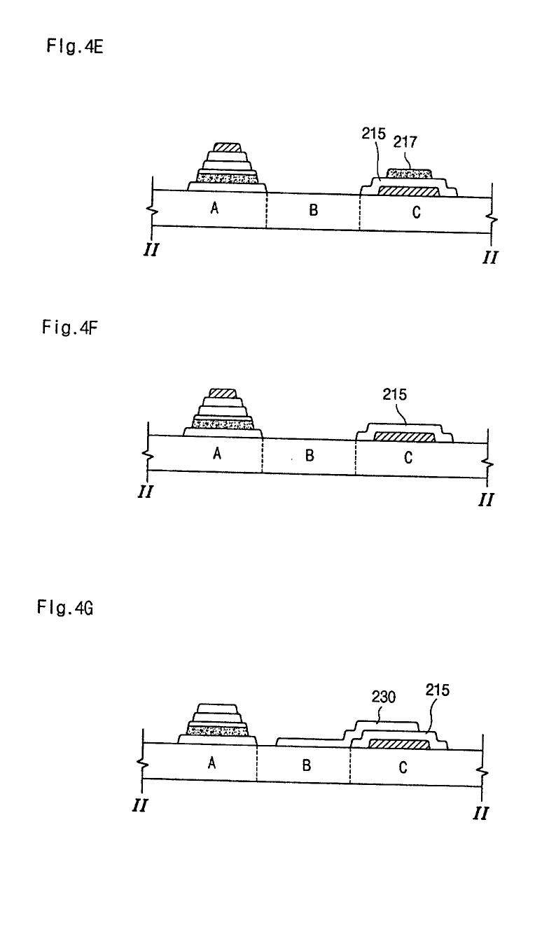

FIGS. 4Ato 4G illustrate a method of manufacturing an array substrate for LCD device according to a second embodiment of the invention. The processes illustrated in FIGS. 4A to 4C are similar to those illustrated in FIGS. 3A to 3C, thus the detailed description is omitted.

On the substrate 211, conductive materials are deposited to form a first metal layer.

Next, using a first mask and through a photolithography process, a gate line 213 is formed. Next, a gate insulating layer 215, a semiconductor layer 217, and a second metal layer are formed sequentially on the whole substrate 211 while covering the gate line 213. The second metal layer has metallic material such as molybdenum or tantalun, which can be etched by a dry etching technique. Through a second mask process, the second metal layer is patterned to form a data line 219 and an island shaped metal portion 221 over the gate line 213. At this time, the data line 219 must have the wider width than that should be made finally. That is, the data line 219 has a surplus margin in width. The margin helps to prevent the layers under the data line from over etching.

Next, a protection layer 223 of insulating material is formed on the semiconductor layer 217 while covering the data line 212 and the metal portion 221.

Next, photoresist is deposited on the protection layer 223 and using a third mask, a portion 225 of the photoresist over the data line 219 remains. Thus, portions of the array substrate can be divided into three portions: “A” portion having photoresist; “B” portion having a sectional structure as gate insulating layer 215, semiconductor layer 217 and protection layer 223; and “C” portion having a sectional structure as gate line 213, gate insulating layer 215, semiconductor layer 217, metal portion 221 and protection layer 223.

The metal portion 221 is to adjust etching rate and to remain the gate insulating layer 215 only on the gate line 213, similar to metal portion 121 of FIG. 3C.

Next, using the photoresist 225, etching steps are processed three times.

FIG. 4D illustrates a first etching step. While etching the protection layer 223 and the semiconductor later 217 at “B” portion, the protection layer 223 and the metal portion 221 are etched. After the etching step, the metal portion 221 can have about a half thickness “t4” than before. At portion “A”, layers under the photoresist 225 remain and the surplus margin “f” of the data line 219 has about a half thickness “t3” than before.

For this purpose, an etching gas can be chosen such that can etch the protection layer 223 and the semiconductor layer 217 more and faster than the metal portion 221 or it is possible to increase the thickness of the metal portion 221 enough to block etching the layers under the metal portion 221 for example over 1300 Å. Or for some metal materials such as molybdenum, below 30% of oxygen gas can be included in the etching gas.

FIG. 4E shows the state of the array substrate after the second etching step. While etching the gate insulating layer 215 at portion “B”, at portion “C” the metal portion 221 is fully etched and the semiconductor layer 217 is somewhat, for example half, etched, and at portion “A” the surplus margin “f” of the data line 219 and the under-positioned layers are etched. The etching condition can be controlled as describe before.

FIG. 4F shows the state of the array substrate after the third etching step. In this step, the semiconductor 217 is fully etched and the gate insulating layer 215 on the gate line 213 remains. In this etching step only one layer is etched, thus it is easy to get the gate insulating layer having a uniform thickness. Since the gate insulating layer 215 act as a dielectric layer for capacitor, uniform thickness of the gate insulating layer 215 on the gate line 213 independent of the position of the pixel region leads to a constant capacitance of the capacitor “Cst” (see FIG. 1) for the LCD device through out the whole pixel regions “P”.

After the third mask process, as shown in FIG. 4G, a transparent conductive material is deposited on the whole substrate, and using a fourth mask a pixel electrode 230 is formed. The pixel electrode is connected to the thin film transistor “T” (see FIG. 1). The pixel electrode also 230 acts as one electrode for the capacitor “C st”, while the gate line 213 acts as the other electrode for the capacitor “Cst”.

As explained above, according to the invention constant capacitance through out the pixel regions can be obtained using only four masks, the display quality cannot be deteriorated in condition of four mask manufacturing method of low production cost.

While the invention has been particularly shown and described with reference to preferred embodiments thereof, it will be understood by those skilled in the art that the foregoing and other changes in form and details may be made therein without departing from the spirit and scope of the invention.

What is claimed is:

1. A method of manufacturing an array panel for use in a liquid crystal display device, comprising:
providing a substrate;
forming a gate line on the substrate using a first mask;
forming sequentially a gate insulating layer, a semiconductor layer having a doped semiconductor layer, and a metal layer on the whole substrate while covering the gate line;
forming a data line and an island shaped metal portion on the semiconductor layer over the gate line by patterning the metal layer using a second mask;
forming a protection layer on the semiconductor layer while covering the data line and the island shaped metal portion;
forming a photoresist pattern on the protection layer over the data line using a third mask to define a first interstructure;
etching the first interstructure using the photoresist pattern to leave the photoresist and the layers under the photoresist over the data line and to leave the etched semiconductor layer and the gate insulating layer over the gate line to define a second interstructure;
etching the second interstructure to leave the gate insulating layer on the gate line; and
forming a pixel electrode covering a portion of the gate insulating layer on the gate line using a fourth mask.

2. The method of claim 1, wherein the etched semiconductor layer on the gate line has a half thickness comparing the semiconductor layer under data line.

3. The method of claim 1, wherein the etchings are processed using a dry etching technique.

4. The method of claim 1, wherein the data line has a metallic material chosen from a group consisting of molybdenum, tantalum, and titanium.

5. A method of manufacturing an array panel for use in a liquid crystal display device, comprising:
providing a substrate;
forming a gate line on the substrate using a first mask;
forming sequentially a gate insulating layer, a semiconductor layer having a doped semiconductor layer, and a metal layer on the whole substrate while covering the gate line;
forming a data line and an island shaped metal portion on the semiconductor layer over the gate line by patterning the metal layer using a second mask;
forming a protection layer on the semiconductor layer while covering the data line and the island shaped metal portion;
forming a photoresist pattern on the protection layer over the data line using a third mask to define a first interstructure;
etching the first interstructure using the photoresist pattern to leave the photoresist and the layers under the photoresist over the data line and to leave the island shaped metal portion and semiconductor layer and the gate insulating layer over the gate line to define a second interstructure;
etching the second interstructure to leave the semiconductor layer and the gate insulating layer on the gate line to define a third interstructure;
etching the third interstructure to remove the semiconductor layer and the gate insulating layer on the gate line; and
forming a pixel electrode covering a portion of the gate insulating layer on the gate line using a fourth mask.

6. The method of claim 5, wherein the etched semiconductor layer on the gate line has a half thickness comparing the semiconductor layer under data line.

7. The method of claim 5, wherein the etchings are processed using a dry etching technique.

8. The method of claim 5, wherein the data line has a metallic material chosen from a group consisting of molybdenum, tantalum, and titanium.

9. The method of claim 5, wherein the data line has a thickness over 1300 Å.
